(19) United States
(12) Patent Application Publication
(10) Pub. No.: US 2005/0093175 A1
(43) Pub. Date: May 5, 2005

(54) Arrangement for improving the reliability of semiconductor modules

(76) Inventors: Martin Reiss, Ottendorf-Okrilla OT Medingen (DE); Steffen Kroehnert, Dresden (DE); Sven Rzepka, Dresden (DE)

Correspondence Address: SLATER & MATSIL LLP, 17950 PRESTON ROAD, SUITE 1000, DALLAS, TX, 75252, US

(21) Appl. No.: 10/979,579

(22) Filed: Nov. 2, 2004

(30) Foreign Application Priority Data
Nov. 3, 2003 (DE) 103 51 544.5
Jul. 29, 2004 (DE) 10 2004 036 908.9

(51) Int. Cl. H01L 23/48; H01L 21/48

(52) U.S. Cl. 257/783; 257/787; 438/118; 438/127

(57) ABSTRACT

A module includes a substrate and a chip attached to the substrate by a die attach material. An intermediate layer is disposed over a surface of the chip. The intermediate layer comprises a compliant material. A mold cap surrounds the surface of the chip such that the intermediate layer is disposed between the chip and the mold cap.

This application claims priority to German Patent Application 103 51 544.5, which was filed Nov. 3, 2003, and to German Patent Application 10 2004 036 908.9, which was filed Jul. 29, 2004, both of which applications are incorporated herein by reference.

### TECHNICAL FIELD

The present invention relates generally to semiconductor modules and more particularly to a system and method for improving the reliability of semiconductor modules.

### BACKGROUND

One type of substrate-based IC package is referred to as a BGA package, BGA standing for Ball Grid Array. As an example, U.S. Pat. No. 6,048,755, which is incorporated herein by reference, discloses a BGA package of this type with a chip. It goes without saying that a number of chips or packages may also be arranged next to one another on a common substrate strip (matrix strip). The substrate itself comprises organic films or glass fiber laminates with copper layers laminated on and patterned by etching technology. These layers have contact islands, which are electrically connected to bonding islands on the chip via wire bridges. The wire bridges extend through a bonding channel in the substrate, on which the chip is mounted with its active side facing downward.

As has already been described, this substrate includes a laminated copper foil, which has been patterned by means of the standard processors (e.g., by photolithography or screen-printing technology), with the result that, in addition to the contact islands, interconnects and what are known as landing pads (contact surfaces) for the solder balls are also produced, the landing pads each being connected to at least one interconnect.

In the case of substrate-based packages of this type, the mold cap, consisting of a plastics material (molding compound), serves to protect the chip and also the edges of the chip. The mold cap encapsulates the rear side of the chip and adjoining regions of the substrate, providing sufficient protection for the sensitive chip edges. In the case of what is known as the one-step molding process, the molding cap, which encapsulates the chip and at the same time closes off the bonding channel is produced in a single operation. This produces a fixed connection between the rear side of the chip and its side edges and the molding compound.

In packages of this type, the chip can be fixed to the substrate in various ways. For example, the chips are usually attached to the substrate by means of a tape or a printed or dispensed adhesive while sufficient contact pressure is being applied. It is particularly effective for the adhesive to be printed onto the substrate via a printing stencil and then for the chip to be adhesively bonded to the substrate.

In the case of the die attach process, the electrical connection of the bonding pads on the chip to the contact islands on the substrate is effected with the aid of wire bridges which are drawn through the bonding channel in the substrate. The bonding channel is then closed off by a molding compound or other plastics material in order to protect the wire bridges, with the molding cap that encapsulates the chip generally being formed at the same time.

In the case of these substrate-based packages for integrated circuits, in particular in the case of ball grid arrays with rear-side protection, difficulties continue to exist in terms of their reliability following mounting on a printed circuit board. This relates in particular to the thermal cycles at module level and the resulting stress states. The failures caused as a result arise in particular due to cracks and detachment of the solder balls during thermal cycles, i.e., during reliability testing of the packages and also during their normal use. These cracks and detachments of the solder balls are induced by the different expansion coefficients of the individual materials involved in mounting (chip, substrate, printed circuit board). These cracks and detachments of the solder balls then lead to failure of the chip and to malfunctioning of the module.

In most cases, the semiconductor material (chip) has a lower expansion coefficient (CTE) than the material of the substrate. The differences in the thermal expansion between these materials take effect in the event of any change in temperature, which inevitably occurs during the production and mounting process and during use of the modules, since they are heated or cooled, in some cases uniformly and in some cases unevenly, or even heat themselves.

The module printed circuit and the package having the chip on the side remote from the printed circuit board each have a greater rigidity than the soldered joints that are present between them. Therefore, the difference in the thermal expansion has to be compensated for by deformation of the soldered joints. This deformation primarily occurs not through plastic flow and creep. The result is cracks or detachments of the soldered joints, which can produce loose contacts or interruptions in the contact. The ultimate result is total failure of the entire module.

One of the main causes of the problems described has proven to be the hard coupling of the molding compound to the chip rear side (bare silicon).

This problem arises in particular in the case of large chips, since in these cases thermally induced forces acting on the solder balls at critical positions are particularly high.

To reduce these problems, it has been attempted to provide suitable design changes in the connection zone between printed circuit board and package (e.g., special soldering stop masks or configuration of the soldering pads) and as an alternative and/or in addition to use optimized materials for mounting. However, for time reasons alone it is not possible to constantly adapt the materials involved in mounting to the chip side, since the adaptation of materials always requires a very long lead time.

Another option for overcoming the problems that have been outlined is described in German Patent Application No. 198 13 525 A1, in which a chip is mounted on a laminate that is reinforced with glass fibers and is for its part mounted on a silicon substrate. This arrangement is encapsulated on the chip side by a molding compound or a potting compound. In addition, a reinforcing layer is applied to the outer side in order to increase the rigidity, producing a sandwich structure.

On account of the considerable technical outlay, a sandwich structure of this type is restricted to particular applications.

### SUMMARY OF THE INVENTION

In one aspect, the invention relates to an arrangement for improving the module reliability of semiconductor modules with BGA or BGA-like components, having a substrate, to which chips are attached using a die attach material, in particular substrate-based IC packages, contact pads for receiving solder balls being provided on the opposite side of the substrate from the chip, for electrical connection to printed circuit boards, and the chip and the substrate being provided with a mold cap on the chip side. For example, embodiments provide an arrangement for improving the module reliability of semiconductor products, in which in particular the thermally induced expansion of the chips has only minor effects on the module reliability and which can be realized with the minimum possible outlay.

In an arrangement for improving the reliability of semiconductor modules with BGA or BGA-like components having a substrate to which chips are attached using a die attach material, in particular substrate-based IC packages, contact pads for receiving solder balls being provided on the opposite side of the substrate from the chip, for electrical connection to printed circuit boards, and the chip and the substrate being provided with a mold cap on the chip side, the object on which the invention is based is achieved by the fact that at least one intermediate layer, which eliminates or reduces the adhesion forces between the rear side of the chip and the mold cap, is arranged at least between the rear side of the chip and the mold cap, and that the connection between the chip and the substrate consists of a soft or foamed material.

Embodiments of the invention significantly reduce or interrupt the coupling of forces from the chip to the mold cap and thereby advantageously influences the warpage of the module.

In a first configuration of the invention, the intermediate layer consists of a soft, highly stretchable material with a low modulus of elasticity.

In a refinement of the invention, the intermediate layer is additionally arranged between the side faces of the chip and the mold cap, so that the chip is for the most part surrounded by the intermediate layer. This significantly reduces the introduction of forces, induced by thermal expansion, to the mold cap and thereby greatly reduces the bending of the housing caused by the different expansion coefficients of the materials used.

Suitable intermediate layers include plastics, such as adhesives, lacquers or films, for example including resists, and also parting agents; a tape which is already in use for chip mounting is also suitable, and other films can also be employed.

In a further configuration of the invention, the intermediate layer has a predetermined flexibility and/or elasticity.

If plastics or resists are used as a parting agent, it is possible for these materials to be applied in a simple way by printing, dispensing, spraying or wetting.

To achieve defined thermal properties, it is also possible for the parting agents to be provided with additives, such as silicon, ceramic or metal powders. However, measures of this type are only employed if the chip reaches relatively high temperatures in operation.

If films or tapes are used as a parting agent, they can easily be laminated onto the rear side of the chip.

One particular configuration of the invention is distinguished by the intermediate layer between the chip and the mold cap comprising a thin film of a suitable liquid or a foam. This liquid should have approximately the consistency of water or wax.

Silicone or wax are particularly suitable for the intermediate layer, since these materials have good wetting properties.

Finally, it is also possible to use standard parting agents, which prevent the formation of adhesion forces between adjacent surfaces, i.e., the rear side of the chip and the mold cap.

The core concept of the invention consists in avoiding or at least greatly reducing the rigid connection, which has hitherto been customary between the chip and the material surrounding it. This enables the chip to move inside the package, within certain limits. In this way, it is possible to provide sufficient compensation for the difference in thermal expansion between the chip, on the one hand, and the remainder of the package, which includes the mold cap and the substrate of the package, as well as the module printed circuit board, on the other hand. This greatly reduces the loading on the soldered joints.

### DESCRIPTION OF THE DRAWINGS

The invention is explained in more detail below on the basis of an exemplary embodiment. In the drawings which belong to the exemplary embodiment:

FIG. 1 shows a diagrammatic sectional illustration of an IC package according to the invention with a flexible interlayer on the rear side of the chip;

FIG. 2 shows a variant of the IC package shown in FIG. 1, in which the chip is additionally provided with a chip edge protection; and

FIG. 3 shows the IC package shown in FIG. 2 with an additional form fit between the mold cap and the substrate.

The following list of reference symbols can be used in conjunction with the figures:

| | |
|---|---|
| 1 | Substrate |
| 2 | Soldering stop resist |
| 3 | Chip |
| 4 | Die attach material |
| 5 | Solder ball |
| 6 | IC package |
| 7 | Mold cap |
| 8 | Intermediate layer |
| 9 | Chip edge |
| 10 | Chip edge protection |
| 11 | Hole in the substrate |

### DETAILED DESCRIPTION OF ILLUSTRATIVE EMBODIMENTS

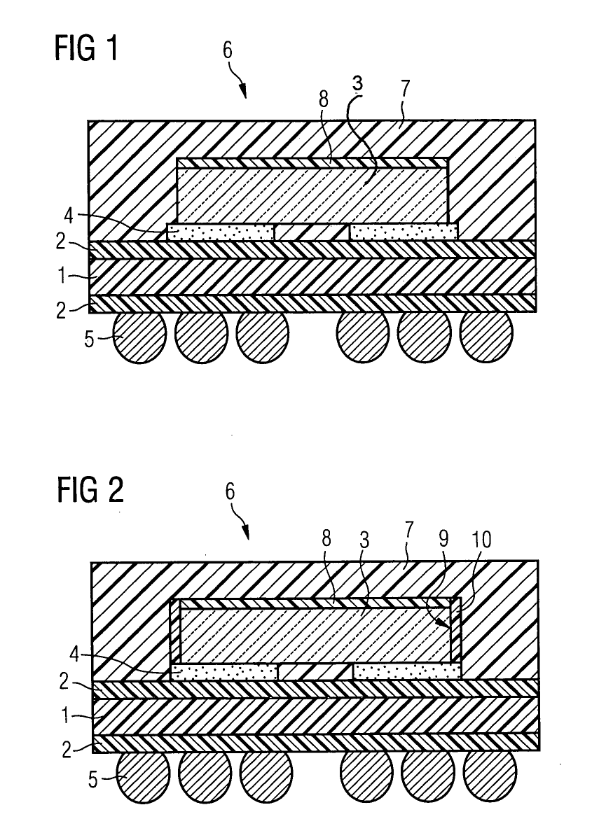

The arrangement according to the preferred embodiment of the invention as shown in FIG. 1 comprises a substrate 1, which is at least partially coated with a soldering stop resist 2 on both sides. A chip 3 is attached to the top side of the substrate 1, as seen in the drawing, by die bonding. A standard die attach material 4 (attachment material formed from an adhesive film or an adhesive) can be used to attach the chip 3 to the substrate 1. The die attach material 4 used is typically a tape or an adhesive paste.

Contact pads and interconnects (not shown) are located on the opposite side of the substrate 1 from the chip 3. As an example, the contact pads and interconnects can be produced from a photolithographically patterned copper foil. These contact pads serve to receive solder balls 5 for electrical connection of the IC package 6 to a printed circuit board (not shown).

The chip 3 and parts of the substrate 1 are provided with a mold cap 7 (e.g., a covering formed from a plastic material). This mold cap serves to protect the chip 3.

To reduce the introduction of forces from the chip 3 to the mold cap 7, an intermediate layer 8 in the form of a flexible interlayer is arranged between the rear side of the chip 3 adjacent to the mold cap 7. This intermediate layer 8 may comprise a plastic, a resist or also a sufficiently elastic plastic film with a predetermined flexibility and/or elasticity. Alternatively, the intermediate layer 8 can comprise a liquid, e.g., with a consistency of water or wax, such a silicone as an example. If the intermediate layer 8 is a plastic film (e.g., tape), the latter can be laminated onto the rear side of the chip 3.

If the intermediate layer 8 comprises a plastic or a resist, it can easily be applied to the rear side of the chip 3 by spraying, dispensing or printing. In addition, the intermediate layer 8 may be provided with additives, such as silicon, ceramic (e.g., Al₂O₃) or metal powder, in order to influence the thermal properties. However, a measure of this nature is only appropriate if the chips 3 reach relatively high operating temperatures during normal use.

FIG. 2 illustrates a variant of the invention, in which the chip edges 9 are additionally provided with a chip edge protection 10, which performs the same function as the intermediate layer 8 and is arranged between the chip edges 9 and the mold cap 7. In an alternate embodiment, not shown, the chip protection material can be formed on the sidewalls without formation on the upper surface.

As has already been explained, the mechanical conditions can be adjusted between “no contact” and a “soft contact” between the chip 3 and the remainder of the package by the addition of a liquid or a very soft material in the space between the chip 3 and the package, as intermediate layer 8.

For example, if a die attach material is required to attach the chip 3 to the substrate 1 (as is customary in the case of wire bonding), a particularly soft adhesive or a particularly soft tape 4 should be used to attach the chip 3. The other sides of the chip 3 may either be coated with a thin film of a liquid having a consistency between that of water and wax or may be covered with a very soft film. It is also possible to use a parting agent as intermediate layer 8. To provide popcorning effects, it is recommended to ensure that the coating is continuous without any gaps. This prevents the possibility of the molding compound (and also the substrate 1) being fixedly joined to the surface of the chip 3.

An example of a suitable intermediate layer 8 or parting agent is silicone. The silicone can be sprayed onto the chip 3 immediately before the cap molding, so that a continuous film is formed. In this case, however, the uncovered region of the substrate should be protected in order to ensure sufficient adhesion between the molding compound and the substrate.

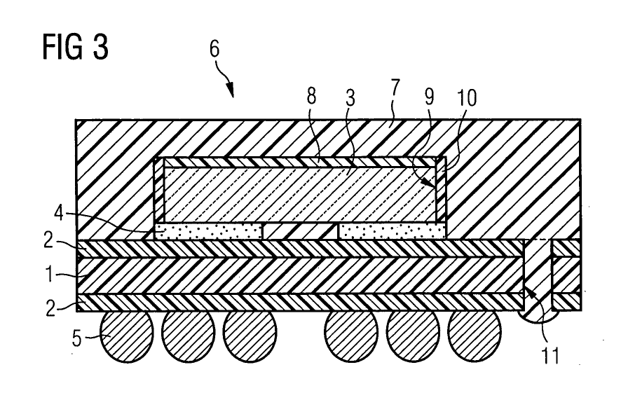

An alternate embodiment is shown in FIG. 3. In this case, the adhesion between the molding cap 7 and the substrate 1 can be enhanced by a form fit by holes 11. For example, holes 11 can be introduced into the substrate 1 and the molding compound can be allowed to pass through these holes during capping. As a result, connecting elements that act like rivets are formed.

It is also possible for liquids other than silicone to be used as intermediate layer 8. What is desired is a film, preferably a continuous film, that prevents a rigid connection to the mold cap be produced between the surface of the chip 3 and the mold cap 7.

If a very soft tape 4 or a foamed material which does not adhere to the chip 3 is used as the intermediate layer, the tape 4 should be at least temporarily fixed to the chip 3, e.g., by clips or similar measures. The tape 4 may also be pulled tight over the chip 3.

An organic material or a metal may be used as intermediate layer 8 on the chip 3. If the intermediate layer 8 consists of a soft material and is electrically insulating, this layer may also bond to the chip 3.

The preferred embodiment of the invention significantly reduces or almost completely prevents the introduction of forces from the chip 3 to the mold cap 7 as a result of thermal expansion, and thereby significantly improves the bending properties of the housing.

1. A module comprising:
a substrate;
a chip attached to the substrate using a die attach material;
an intermediate layer disposed over a surface of the chip, the intermediate layer comprising a compliant material; and
a mold cap surrounding the surface of the chip such that the intermediate layer is disposed between the chip and the mold cap.

2. The module of claim 1, wherein the die attach material comprises tape.

3. The module of claim 1, and further comprising solder balls attached to the substrate on a surface opposed to a surface that receives the chip.

4. The module of claim 1, wherein the intermediate layer eliminates or reduces adhesion forces between the chip and the mold cap.

5. The module of claim 1, wherein the die attach material comprises a soft or foamed material.

6. The module of claim 1, wherein the intermediate layer comprises a material with elastic properties.

7. The module of claim 1, wherein the intermediate layer overlies an upper surface of the chip and also overlies side surfaces of the chip, the mold cap formed over the upper surface and the side surfaces.

8. The module of claim 1, wherein the intermediate layer comprises a plastic.

9. The module of claim 1, wherein the intermediate layer comprises a material selected from the group consisting of an epoxy resin, a resist and a parting agent.

10. The module of claim 1, wherein the intermediate layer comprises a material with additives.

11. The module of claim 10, wherein the additives comprise semiconductor, ceramic or metal powders.

12. The module of claim 1, wherein the intermediate comprises a foam.

13. The module of claim 1, wherein the intermediate comprises a film of a liquid.

14. The module of claim 13, wherein the liquid has approximately the consistency of water or wax.

15. The module of claim 1, wherein the intermediate layer comprises silicone.

16. The module of claim 1, wherein the intermediate layer comprises wax.

17. The module of claim 1, wherein the substrate includes at least one hole formed therethrough and wherein material of the mold cap extends through the at least one hole.

18. An arrangement for improving the module reliability of semiconductor modules with BGA or BGA-like components, the arrangement comprising:
a substrate to which chips are attached using a die attach material, wherein the die attach material comprises a soft or foamed material;
contact pads for receiving solder balls being provided on the opposite side of the substrate from the chip, the solder balls for electrical connection to printed circuit boards;
a mold cap wherein the chip and the substrate are provided with the mold cap on the chip side; and
at least one intermediate layer that eliminates or reduces adhesion forces between the rear side of the chip and the mold cap and is arranged at least between the rear side of the chip and the mold cap.

19. A method of forming a module, the method comprising:
attaching a lower main surface of a semiconductor chip to an upper surface of a substrate;
forming an intermediate layer over an upper main surface of the semiconductor chip, the intermediate layer comprising a compliant material; and
forming a mold cap over the upper main surface of the semiconductor chip such that the intermediate layer is disposed between the upper main surface of the semiconductor chip and the mold cap.

20. The method of claim 19 wherein forming an intermediate layer over the upper main surface further comprises forming an intermediate layer over side surfaces of the semiconductor chip.

21. The method of claim 19 wherein forming a mold cap further comprises forming mold cap material within a hole that extends through the substrate.

22. The method of claim 19 wherein forming the intermediate layer comprises pressing an intermediate layer material onto the upper main surface of the chip.

23. The method of claim 19 wherein forming the intermediate layer comprises dispensing an intermediate layer material over the upper main surface side of the chip.

24. The method of claim 19 wherein forming the intermediate layer comprises spraying an intermediate layer material over the upper main surface side of the chip.

25. The method of claim 19 wherein forming the intermediate layer comprises wetting an intermediate layer material over the upper main surface side of the chip.

26. The method of claim 19 wherein forming the intermediate layer comprises laminating an intermediate layer material onto the upper main surface side of the chip.

27. The method of claim 19 wherein forming the intermediate layer comprises spraying a parting agent onto the upper main surface of the chip.

28. The method of claim 19 wherein forming the intermediate layer comprises forming a silicone layer.
